(19) United States
(12) Patent Application Publication
(10) Pub. No.: US 2016/0299388 A1
(43) Pub. Date: Oct. 13, 2016

(54) DISPLAY DEVICE

(71) Applicant: Samsung Display Co., Ltd., Yongin-Si (KR)

(72) Inventors: Sang-Myoung LEE, Seoul (KR); Hyun-Ho KANG, Ansan-si (KR); O Sung SEO, Seoul (KR); Seung Jun YU, Cheonan-si (KR); Ha Won YU, Suwon-si (KR); Ki Kyung YOUK, Bucheon-si (KR); Yeo Geon YOON, Suwon-si (KR)

(21) Appl. No.: 15/092,940

(22) Filed: Apr. 7, 2016

(30) Foreign Application Priority Data
Apr. 10, 2015 (KR) 10-2015-0051078

(51) Int. Cl. G02F 1/1343; G02F 1/1368; G02F 1/1362; H01L 27/12

(52) U.S. Cl. CPC G02F 1/134309; H01L 27/124; G02F 1/1368; G02F 1/13624; G02F 2001/134345

(57) ABSTRACT

A display device may include a first transistor, a second transistor, a third transistor, a data line, a pixel electrode member, and a reference voltage line. The first transistor includes a first source and a first drain. The second transistor includes a second source and a second drain. The third transistor includes a third drain. The data line is electrically connected to each of the first source and the second source. The pixel electrode member is electrically connected to the first drain. The reference voltage line is electrically connected to the third drain and includes a first bar and a second bar. The pixel electrode member overlaps both the first bar and the second bar. The first bar extends perpendicular to the data line. The second bar extends parallel to the data line and is directly connected to a center portion of the first bar.

### CROSS-REFERENCE TO RELATED APPLICATION

This application claims priority to and the benefit of Korean Patent Application No. 10-2015-0051078 filed in the Korean Intellectual Property Office on Apr. 10, 2015; the entire contents of the Korean Patent Application are incorporated herein by reference.

### BACKGROUND

(a) Technical Field

The technical field relates to a display device.

(b) Description of the Related Art

A liquid crystal display may include electric field generating electrodes (such as a pixel electrode and a common electrode) and a liquid crystal layer. The liquid crystal display may apply a voltage to the electric field generating electrodes to generate an electric field in the liquid crystal layer, thereby determining a direction of liquid crystal molecules of the liquid crystal layer, for controlling transmission of incident light to display an image. The electric field generating electrodes may be implemented on two opposite substrates. Misalignment of the substrates may cause an unwanted texture and/or an undesirable luminance associated with a displayed image.

The above information disclosed in this Background section is for enhancement of understanding of the background of this application. The Background section may contain information that does not form the prior art that is already known in this country to a person of ordinary skill in the art.

### SUMMARY

An embodiment may be related to a display device. The display device may include a first transistor, a second transistor, a third transistor, a data line, a first pixel electrode member, and a reference voltage line. The first transistor may include a first source and a first drain. The second transistor may include a second source and a second drain. The third transistor may include a third drain and may be electrically connected to the first transistor or the second transistor. The data line may be electrically connected to each of the first source and the second source. The first pixel electrode member may be electrically connected to the first drain. The reference voltage line may be electrically connected to the third drain and may include a first bar and a second bar. The first pixel electrode member may overlap both the first bar and the second bar. The first bar may extend perpendicular to the data line. The second bar may extend parallel to the data line and may be directly connected to a center portion of the first bar.

Two equal-length sections of the first bar may be positioned at two opposite sides with respect to the second bar.

The third transistor may include a third source, which may be electrically connected to the first drain.

The display device may include a first shielding electrode, a second shielding electrode, and an insulating material layer. The first shielding electrode may overlap the data line. The first pixel electrode member may be electrically insulated from the first shielding electrode and may be positioned between two portions of the first shielding electrode. The second shielding electrode may immediately neighbor the first shield electrode, may be asymmetrical, and may be a mirror image of the first shield electrode in a plan view of the display device. The insulating material layer may directly contact each of the first shielding electrode and the first pixel electrode member.

The first pixel electrode member may include a first base and a first branch. The first branch may overlap the first bar and may be directly connected to an edge of the first base. Two parallel sides of the first branch may be slanted with respect to the first bar. The second bar may divide the first base into two equal-size portions in a plan view of the display device.

The first branch may overlap both the first bar and the second bar.

The first branch may be not longer than any other branch that is directly connected to the first base.

The edge of the first base may be slanted with respect to the second bar.

The edge of the first base may be curved.

Each of the two equal-size portions of the first base may have an outer edge that is slanted with respect to the second bar or is curved.

The reference voltage line may include a third bar, which may overlap the first pixel electrode member. A first end of the second bar may be directly connected to the center portion of the first bar. A second end of the second bar may be directly connected to a center part of the third bar.

The display device may include a second pixel electrode member, which may be electrically insulated from the first pixel electrode member and may be electrically connected to the second drain. The reference voltage line may include a third bar and a fourth bar. The second pixel electrode member may overlap both the third bar and the fourth bar. The third bar may extend perpendicular to the data line. The fourth bar may extend parallel to the data line and may be directly connected to a center part of the third bar.

The third transistor may include a third source, which may be electrically connected to the second drain.

The first pixel electrode member may include a first base and a first branch. The first branch may overlap the first bar and may be directly connected to an edge of the first base, wherein two parallel sides of the first branch may be slanted with respect to the first bar. The second bar divides the first base into two equal-size portions in a plan view of the display device. The second pixel electrode member may include a second base and a second branch. The second branch may overlap the third bar and may be directly connected to an edge of the second base, wherein two parallel sides of the second branch may be slanted with respect to the third bar. The fourth bar divides the second base into two equal-size parts in the plan view of the display device.

The edge of the first base may be slanted with respect to the fourth bar. The edge of the second base may be perpendicular to the fourth bar,

The edge of the first base may be curved. The edge of the second base may be perpendicular to the fourth bar,

The display device may include a third pixel electrode member, which may be electrically connected to the second pixel electrode member. The reference voltage line may include a fifth bar and a sixth bar. The third pixel electrode member may overlap the sixth bar. The fifth bar may extend perpendicular to the data line and may be shorter than at least one of the first bar and the third bar. A first end of the fifth bar may be directly connected to the fourth bar. A second end of the fifth bar may be directly connected to the sixth bar.

A length of the fifth bar may be less than or equal to a half of a length of the first bar.

The sixth bar may be as long as the second bar and may be not aligned with the second bar.

The sixth bar may be as long as the fourth bar and may be not aligned with the fourth bar.

An embodiment may be related to a display device that includes the following elements: a first insulation substrate; a thin film transistor positioned on the first insulation substrate; a pixel electrode connected to the thin film transistor and including a first sub-pixel electrode and a second sub-pixel electrode; a second insulation substrate facing the first insulation substrate; and a common electrode positioned on the second insulation substrate, wherein the pixel electrode includes a first basic electrode and a second basic electrode. The first basic electrode includes an integrated plate electrode positioned at the center thereof and a plurality of fine branch portions extending from the integrated plate electrode in a diagonal direction. The second basic electrode includes a horizontal stem portion, a vertical stem portion positioned at one end of the horizontal stem portion, and a plurality of fine branch portions extending from the horizontal stem portion in the diagonal direction.

The pixel electrode may further include a third basic electrode, which includes a cross-shaped structure and a plurality of fine branch portions extending from the cross-shaped structure in the diagonal direction.

The cross-shaped structure may include a horizontal stem and a vertical stem perpendicular to the horizontal stem.

The first sub-pixel electrode may include the first basic electrode, and the second sub-pixel electrode may include the second basic electrode and the third basic electrode.

The second basic electrode and the third basic electrode may be connected to each other.

The first sub-pixel electrode may include the second basic electrode, and the second sub-pixel electrode may include the first basic electrode and the third basic electrode.

The first basic electrode and the third basic electrode may be connected to each other.

The first sub-pixel electrode may include the third basic electrode, and the second sub-pixel electrode may include the first basic electrode and the second basic electrode.

The first basic electrode and the second basic electrode may be connected to each other.

The integrated plate electrode may have a rhombus shape or a circular shape.

Left-side vertical stem portions and right-side vertical stem portions of pixel electrodes arranged in a column direction may be alternately positioned.

Left-side vertical stem portions and right-side vertical stem portions of pixel electrodes arranged in a row direction may be alternately positioned.

The first sub-pixel electrode may include the first basic electrode, and the second sub-pixel electrode may include the second basic electrode.

The second sub-pixel electrode may include a first horizontal basic electrode including a first horizontal stem portion, a first vertical stem portion positioned at one end of the first horizontal stem portion, and a plurality of fourth fine branch portions extending from the first horizontal stem portion in the diagonal direction, and a second horizontal basic electrode including a second horizontal stem portion, a second vertical stem portion positioned at one end of the second horizontal stem portion, and a plurality of fifth fine branch portions extended from the second horizontal stem portion in the diagonal direction.

First vertical stem portions and second vertical stem portions may be alternately positioned.

A ratio of areas of the first sub-pixel electrode and the second sub-pixel electrode may be about 1:2.

The first sub-pixel electrode may include the second basic electrode, and the second sub-pixel electrode may include the first basic electrode.

A ratio of areas of the first sub-pixel electrode and the second sub-pixel electrode may be about 1:2.

The display device may have a curved shape.

According embodiments, even if substrates of a display device are misaligned, unwanted texture in a displayed image may be minimized or substantially prevented, and satisfactory transmittance, visibility, and/or luminance associated with a displayed image may be attained.

In addition, other features and advantages may be newly recognized through embodiments.

### BRIEF DESCRIPTION OF THE DRAWINGS

FIG. 1 is a schematic circuit diagram of one pixel according to an embodiment.

FIG. 2 is a schematic plan view of one pixel according to an embodiment.

FIG. 3 is a schematic cross-sectional view taken along line of FIG. 2.

FIG. 4 is a schematic plan view of a data conductor layer according to an embodiment.

FIG. 5 is a schematic plan view of a pixel electrode layer according to an embodiment.

FIG. 6 is a schematic plan view showing a plurality of pixel electrodes according to an embodiment.

FIG. 7 is a schematic plan view showing a plurality of pixel electrodes according to an embodiment.

FIG. 8, FIG. 9, FIG. 10, FIG. 11, FIG. 12, and FIG. 13 are schematic plan views of pixel elements according to one or more embodiments.

FIG. 14, FIG. 15, FIG. 16, and FIG. 17 are schematic circuit diagrams of pixels according to one or more embodiments.

### DETAILED DESCRIPTION OF EMBODIMENTS

Some embodiments are described with reference to the accompanying drawings,. As those skilled in the art would realize, the described embodiments may be modified in various ways.

Although the terms “first”, “second”, etc. may be used herein to describe various elements, these elements should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used to differentiate different categories or sets of elements.

For conciseness, the terms “first”, “second”, etc. may represent, for example, “first-category (or first-set)”, “second-category (or second-set)”, etc., respectively.

In the drawings, thicknesses of layers, films, panels, regions, etc., may be exaggerated for clarity. Like reference numerals may designate like elements in this application. When a first element (such as a layer, film, region, or substrate) is referred to as being “on” a second element, the first element can be directly on the second element, or one or more intervening elements may also be present. In contrast, when a first element is referred to as being “directly on” a second element, there are no intervening elements intentionally provided between the first element and the second element.

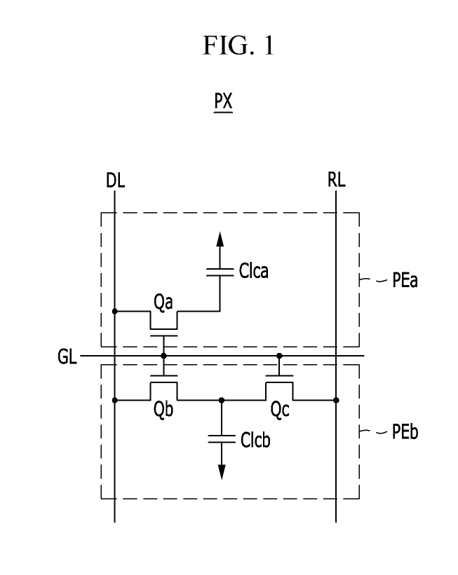

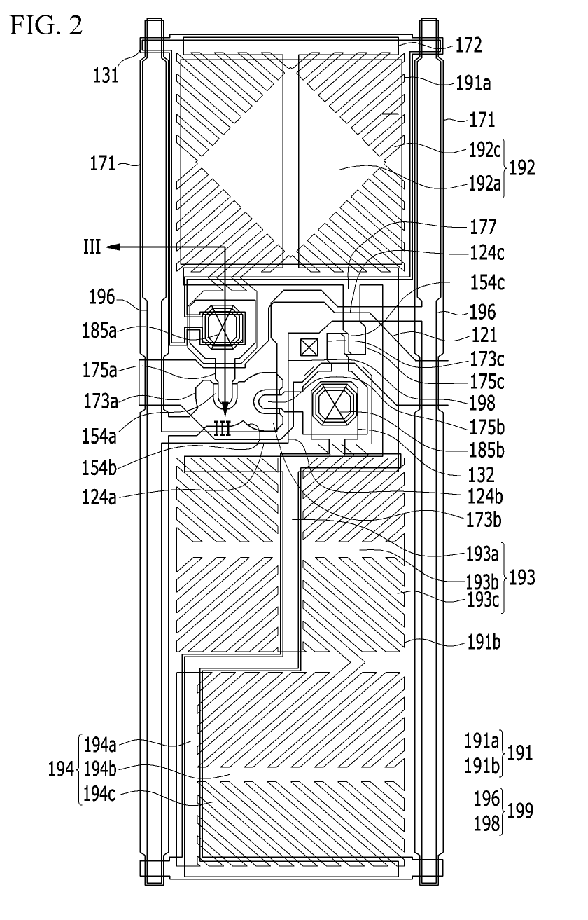

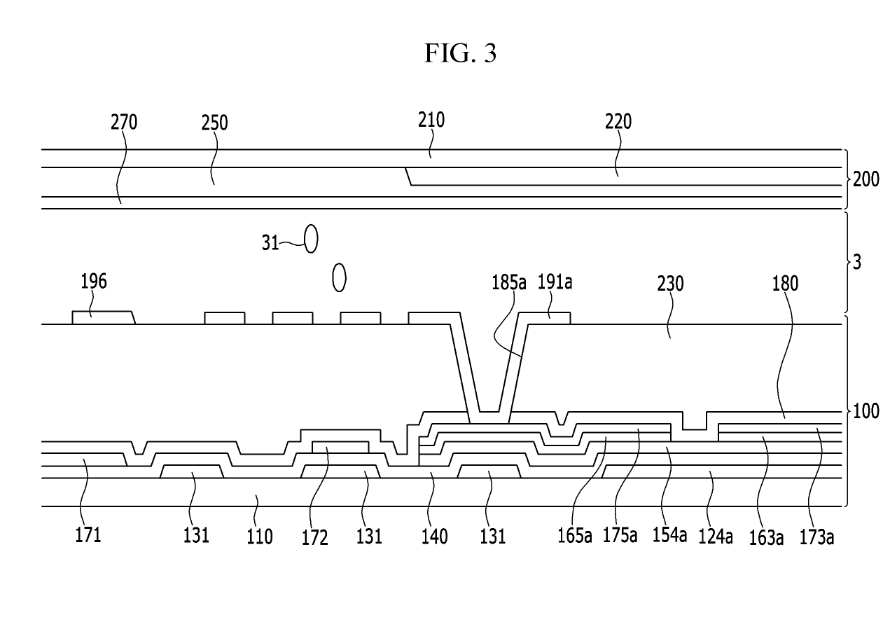

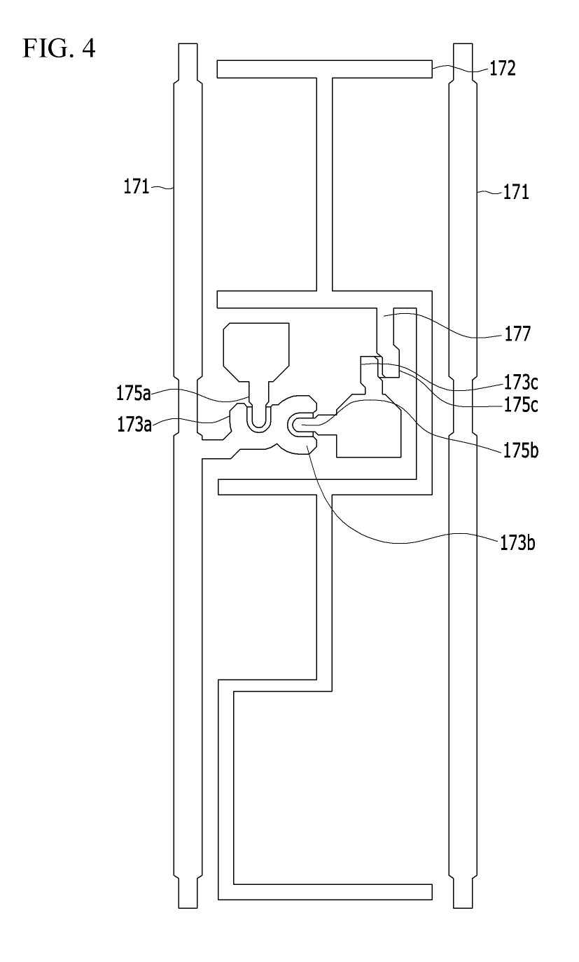

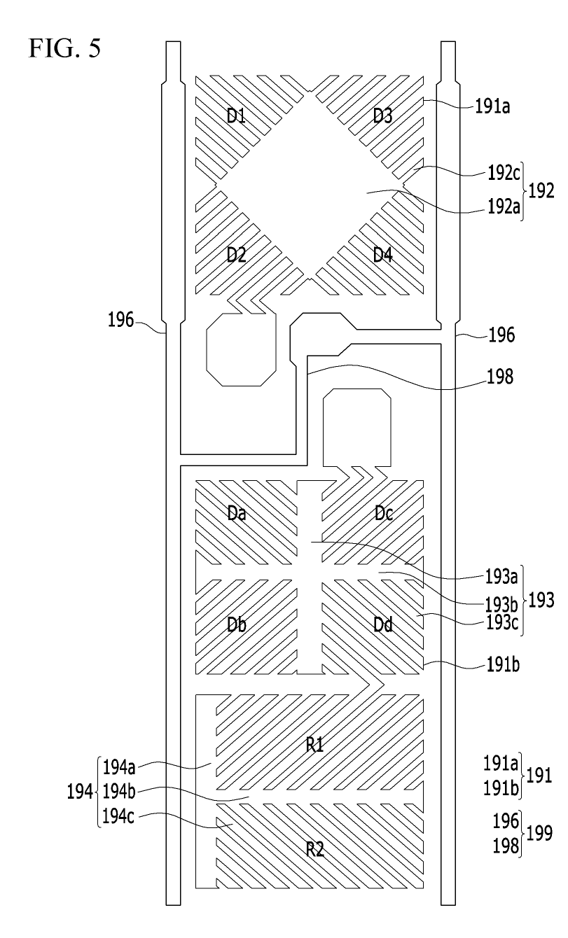

FIG. 1 is a circuit diagram of one pixel according to an embodiment, FIG. 2 is a plan view of one pixel according to an embodiment, FIG. 3 is a cross-sectional view taken along line of FIG. 2, FIG. 4 is a plan view of a data conductor layer according to an embodiment, and FIG. 5 is a plan view of a pixel electrode layer according to an embodiment.

First, referring to FIG. 1, one pixel PX of a display device according to the present embodiment includes a plurality of signal lines including a gate line GL transferring a gate signal, a data line DL transferring a data signal, and a voltage dividing reference voltage line RL transferring a voltage dividing reference voltage and first, second, and third switching elements Qa, Qb, and Qc connected to the plurality of signal lines, and first and second liquid crystal capacitors Clca and Clcb.

Each of the first and second switching elements Qa and Qb is connected to the gate line GL and the data line DL, and the third switching element Qc is connected to an output terminal of the second switching element Qb and the voltage dividing reference voltage line RL.

The first switching element Qa and the second switching element Qb, which are three-terminal elements such as thin film transistors, or the like, have control terminals connected to the gate line GL and input terminals connected to the data line DL, respectively, an output terminal of the first switching element Qa is connected to the first liquid crystal capacitor Clca, and an output terminal of the second switching element Qb is connected to the second liquid crystal capacitor(Clcb) and an input terminal of the third switching element(Qc).

The third switching element Qc, which is also a three-terminal element such as a thin film transistor, has a control terminal connected to the gate line GL, the input terminal connected to the second liquid crystal capacitor Clcb, and an output terminal connected to the voltage dividing reference voltage line RL.

When a gate-on signal is applied to the gate line GL, the first switching element Qa, the second switching element Qb, and the third switching element Qc connected to the gate line are turned on. Therefore, a data voltage applied to the data line DL is applied to a first sub-pixel electrode PXa and a second sub-pixel electrode PXb through the first switching element Qa and the second switching element Qb that are turned on.

Here, the data voltages applied to the first sub-pixel electrode PXa and the second sub-pixel electrode PX are the same as each other, and the first liquid crystal capacitor Clca and the second liquid crystal capacitor Clcb are charged with the same value corresponding to a difference between a common voltage and the data voltage.

At the same time, a voltage charged in the second liquid crystal capacitor Clcb is divided through the turned-on third switching element Qc. The voltage value charged in the second liquid crystal capacitor Clcb is lowered by a difference between the common voltage and the voltage dividing reference voltage. That is, a voltage charged in the first liquid crystal capacitor Clca becomes higher than the voltage charged in the second liquid crystal capacitor Clcb.

As described above, the voltage charged in the first liquid crystal capacitor Clca and the voltage charged in the second liquid crystal capacitor Clcb become different from each other. Since the voltage of the first liquid crystal capacitor Clca and the voltage of the second liquid crystal capacitor Clcb are different from each other, angles at which liquid crystal molecules are inclined in a first sub-pixel and a second sub-pixel are different from each other, such that luminances of two sub-pixels are different from each other. Therefore, when the voltage of the first liquid crystal capacitor Clca and the voltage of the second liquid crystal capacitor Clcb are appropriately adjusted, an image viewed from a side may be as close to an image viewed from a front as possible, such that side visibility may be improved.

Although an embodiment in which the pixel includes the third switching element Qc connected to the second liquid crystal capacitor Clcb and the voltage dividing reference voltage line RL in order to make the voltage charged in the first liquid crystal capacitor Clca and the voltage charged in the second liquid crystal capacitor Clcb different from each other has been shown, in the case of a liquid crystal display according to an embodiment, the second liquid crystal capacitor Clcb may also be connected to a step-down capacitor. In detail, the pixel includes a third switching element including a first terminal connected to a step-down gate line, a second terminal connected to the second liquid crystal capacitor Clcb, and a third terminal connected to the step-down capacitor to allow some of electric charges charged in the second liquid crystal capacitor Clcb to be charged in the step-down capacitor, thereby making it possible to set voltages charged in the first liquid crystal capacitor Clca and the second liquid crystal capacitor Clcb to be different from each other. In addition, in the case of the liquid crystal display according to an embodiment, the first liquid crystal capacitor Clca and the second liquid crystal capacitor Clcb are connected to different data lines to receive different data voltages, thereby making it possible to set voltages charged in the first liquid crystal capacitor Clca and the second liquid crystal capacitor Clcb to be different from each other. Voltages charged in the first liquid crystal capacitor Clca and the second liquid crystal capacitor Clcb may be set to be different from each other by several methods other than the above-mentioned method. It will be described blow in more detail in a description of FIGS. 12 to 15.

Next, referring to FIGS. 2 to 3, gate conductors including gate lines 121 and sustain electrode lines 131 and 132 are positioned on a first insulation substrate 110 made of transparent glass, plastic, or the like. The gate lines 121 include a wide end portion (not shown) for a contact with gate electrodes 124a, 124b, and 124c, and another layer or an external driving circuit.

The gate line 121 and the sustain electrode lines 131 and 132 may be made of an aluminum based metal such as aluminum (Al), an aluminum alloy, or the like, a silver based metal such as silver (Ag), a silver alloy, or the like, a copper based metal such as copper (Cu), a copper alloy, or the like, a molybdenum based metal such as molybdenum (Mo), a molybdenum alloy, or the like, chromium (Cr), tantalum (Ta) and titanium (Ti), or the like. The gate line 121 may also have a multilayer structure including at least two conductive layers having different physical properties.

The gate line 121 traverses a pixel area in a column direction. A first sub-pixel electrode 191a displaying a high gray may be positioned above the gate line 121, and a second sub-pixel electrode 191b displaying a low gray may be positioned below the gate line 121, and vice versa.

The sustain electrode lines 131 and 132 may be made of the same material as that of the gate line 121, and may be formed simultaneously with the gate line 121.

A first sustain electrode line 131 positioned above the gate line 121 may have a quadrangular shape in which it encloses the first sub-pixel electrode 191a. A side positioned at the uppermost portion in the first sustain electrode line 131 formed in the quadrangular shape may be horizontally extended beyond one pixel area to thereby be connected to another layer or an external driving circuit.

The second sustain electrode line 132 positioned below the gate line 121 includes a plurality of horizontal portions and a plurality of vertical portions connecting the plurality of horizontal portions to each other at edges of the plurality of vertical portions.

Although the shapes of the sustain electrode lines 131 and 132 as described above have been described and shown in the present specification, the sustain electrode lines 131 and 132 are not limited to having the above-mentioned shapes, but may have any shape for performing the same function.

A gate insulating layer 140 is positioned on the gate conductors. A first semiconductor layer 154a, a second semiconductor layer 154b, and a third semiconductor layer 154c are positioned on the gate insulating layer 140.

A plurality of ohmic contacts 163a, 165a, 163b, 165b, 163c, and 165c are positioned on the semiconductor layers 154a, 154b, and 154c. The plurality of ohmic contacts 163a, 165a, 163b, 165b, 163c, and 165c may be omitted in the case in which the semiconductor layers 154a, 154b, and 154c are made of an oxide semiconductor material.

Data conductor including data lines 171 including source electrodes 173a, 173b, and 173c, drain electrodes 175a, 175b, and 175c, and voltage dividing reference voltage lines 172 are formed on the ohmic contacts 163a, 165a, 163b, 165b, 163c, and 165c and the gate insulating layer 140.

The data conductors, the ohmic contacts, and the semiconductor layers positioned below the data conductors and the ohmic contacts may be simultaneously formed using one mask.

FIG. 4 is a plan view of a data conductor layer according to an embodiment.

The data conductor include the data lines 171, a first source electrode 173a, a second source electrode 173b, a third source electrode 173c, a first drain electrode 175a, a second drain electrode 175b, a third drain electrode 175c, and the voltage dividing reference voltage lines 172.

The data lines 171 extend in a row direction along edges of one pixel area, and include the first source electrode 173a and the second source electrode 173b. The first source electrode 173a and the second source electrode 173b may have a U shape, but are not limited thereto.

The first drain electrode 175a faces the first source electrode 173a, has, for example, an I shape so as to correspond to the first source electrode 173a having the U shape, and includes a widely extended region connected to the first sub-pixel electrode 191a.

The second drain electrode 175b faces the second source electrode 173b, has, for example, an I shape so as to correspond to the second source electrode 173b having the U shape, and includes a widely extended region connected to the second sub-pixel electrode 191b.

The third source electrode 173c extends from one surface of the second drain electrode 175b.

In addition, the data conductor includes the voltage dividing reference voltage lines 172. The voltage dividing reference voltage lines 172 include the third drain electrode 175c forming a thin film transistor together with the third source electrode 173c.

Referring to FIG. 4, the voltage dividing reference voltage line 172 includes a plurality of horizontal portions and vertical portions connecting the plurality of horizontal portions to each other. That is, the voltage dividing reference voltage line 172 includes the plurality of horizontal portions and a plurality of vertical portions connecting the plurality of horizontal portions to each other. The vertical portions may be connected to one end or the center of the horizontal portions that are in parallel with each other.

The voltage dividing reference voltage lines 172 may have different shapes in each of the first sub-pixel electrode 191a and the second sub-pixel electrode 191b. As shown in FIG. 4, the voltage dividing reference voltage line 172 positioned in the first sub-pixel electrode 191a may include two horizontal portions and one vertical portion, and the voltage dividing reference voltage line 172 positioned in the second sub-pixel electrode 191b may include two horizontal portions and two vertical portions. One of the vertical portions may be connected to one ends of the two horizontal portions, and the other of the vertical portions may be positioned in a form in which it extends from the center of one horizontal portion. This is an arrangement depending on a shape of the pixel electrode 191, and shapes of the voltage dividing reference voltage lines 172 may be changed depending on a change in the shape of the pixel electrode. In detail, the voltage dividing reference voltage line 172 positioned in the first sub-pixel electrode 191a partially overlaps distal ends of first fine branch portions 192c of a first basic electrode 192 (or pixel-electrode member 192). In addition, the voltage dividing reference voltage line 172 positioned in the second sub-pixel electrode 191b may be positioned to partially overlap a vertical stem portion 193a (or base 193a) and distal ends of third fine branch portions 193c of a third basic electrode 193 (or pixel-electrode member 193) and partially overlap a vertical stem portion 194a (or base 194a) and distal ends of second fine branch portions 194c of a second basic electrode 194 (or pixel-electrode member 194).

A portion 177 extends from a horizontal portion of the voltage dividing reference voltage line 172 positioned at the lowermost side the first sub-pixel electrode 191a is directly connected to the third drain electrode 175c.

The first gate electrode 124a, the first source electrode 173a, and the first drain electrode 175a described above form one first thin film transistor (TFT) Qa together with the first semiconductor layer 154a. A channel of the first thin film transistor is formed on the first semiconductor layer 154a between the first source electrode 173a and the first drain electrode 175a. Similarly, the second gate electrode 124b, the second source electrode 173b, and the second drain electrode 175b form one second thin film transistor Qb together with the second semiconductor layer 154b. A channel of the second thin film transistor is formed on the second semiconductor layer 154b between the second source electrode 173b and the second drain electrode 175b. Further, the third gate electrode 124c, the third source electrode 173c, and the third drain electrode 175c form one third thin film transistor Qc together with the third semiconductor layer 154c. A channel of the third thin film transistor is formed on the third semiconductor layer 154c between the third source electrode 173c and the third drain electrode 175c.

A passivation layer 180 is positioned on the data conductors and the exposed semiconductor layers 154a, 154b, and 154c.

The passivation layer 180 may be made of an inorganic insulating layer material such as a silicon nitride, a silicon oxide, or the like. In the case in which color filters are provided on the passivation layer 180, the passivation layer 180 prevents pigments of the color filter from being introduced into the exposed semiconductor layers 154a, 154b, and 154c.

The color filters 230 are formed of one or more insulating materials and are positioned on the passivation layer 180, and may uniquely display one of primary colors. An example of the primary colors includes three primary colors such as red, green, blue, yellow, cyan, magenta, or the like. Although not shown, the color filters may further include a color filter displaying a mixed color of the primary colors or a white in addition to the primary colors.

A first contact hole 185a and a second contact hole 185b exposing the first drain electrode 175a and the second drain electrode 175b are positioned in the passivation layer 180 and the color filter 230.

Pixel electrodes 191 are positioned on the color filters 230. The pixel electrode 191 include the first sub-pixel electrode 191a and the second sub-pixel electrode 191b separated from each other with the gate line 121 interposed therebetween and neighboring to each other in the column direction.

The pixel electrode 191 and a shielding electrode 199 according to the present invention will be described with reference to FIG. 5.

First, the pixel electrode 191 includes the first sub-pixel electrode 191a and the second sub-pixel electrode 191b, as described above.

The pixel electrode 191 includes a first basic electrode 192 including an integrated plate electrode 192a (or base 192a) positioned at the center thereof and a plurality of first fine branch portions 192c extended from the integrated plate electrode 192a in a diagonal direction, a second basic electrode including a horizontal stem portion 194b, a vertical stem portion 194a positioned at one end of the horizontal stem portion 194b, and a plurality of second fine branch portions 194c extended from the horizontal stem portion 194b in the diagonal direction, and a third basic electrode 193 including cross-shaped stem portions 193a and 193b (i.e., stems 193a and 193b of a cross-shaped structure) and a plurality of third fine branch portions 193c extended from the cross-shaped stem portions 193a and 193b in the diagonal direction.

Here, according to embodiment, the first sub-pixel electrode 191a includes the first basic electrode 192, and the second sub-pixel electrode 191b includes the second basic electrode 194 and the third basic electrode 193.

The first basic electrode 192 may include the integrated plate electrode 192a positioned at the center thereof and the plurality of first fine branch portions 192c extended from the integrated plate electrode 192a in the diagonal direction. A general outline shape of the first basic electrode 192 is quadrangular.

The integrated plate electrode 192a may be formed in a rhombus shape, and the first fine branch portions 192c are obliquely extending in a direction in which they become distant from each side of the integrated plate electrode 192a.

The first basic electrode 192 is divided into four regions D1, D2, D3, and D4 based on each side of the integrated plate electrode 192a. Each of the four regions includes the plurality of first fine branch portions 192c.

The first fine branch portions 192c positioned in a first region D1 obliquely extend from the integrated plate electrode 192a in a left upward direction, and the first fine branch portions 192c positioned in a second region D2 obliquely extend from the integrated plate electrode 192a in a left downward direction. The first fine branch portions 192c positioned in a third region D3 obliquely extend from the integrated plate electrode 192a in a right upward direction, and the first fine branch portions 192c positioned in a fourth region D4 obliquely extend from the integrated plate electrode 192a in a right downward direction.

Fine slits in which the electrodes are removed are positioned between the first fine branch portions 192c neighboring to each other.

The first fine branch portions 192c form an angle of approximately 45 degrees or 135 degrees with respect to the gate line 121. In addition, the first fine branch portions 192c of two neighboring regions D1, D2, D3, and D4 may be perpendicular to each other. However, according to an embodiment, an angle formed by the first fine branch portions 192c and the gate line 121 may be appropriately adjusted in consideration of display characteristics such as visibility of the liquid crystal display, or the like.

Some of the first fine branch portions 192c extend to form a wide region, thereby receiving a voltage from the first drain electrode 175a exposed through the first contact hole 185a.

Here, sides of the first fine branch portions 192c distort an electric field to generate a horizontal component of the electric field determining an inclination direction of the liquid crystal molecules 31. The horizontal component of the electric field is substantially horizontal to the sides of the first fine branch portions 192c. Therefore, the liquid crystal molecules 31 are inclined in a direction that is in parallel with a length direction of the first fine branch portions 192c. Since the first sub-pixel electrode 191a includes the four regions D1 to D4 in which length directions of the first fine branch portions 192c are different from each other, directions in which the liquid crystal molecules 31 are inclined are approximately four directions, and four domains in which alignment directions of the liquid crystal molecules 31 are different from each other are formed in a liquid crystal layer 3. When directions in which the liquid crystal molecules are inclined are various as described above, a reference viewing angle of the liquid crystal display becomes large.

The second sub-pixel electrode 191b includes the third basic electrode 193. The third basic electrode 193 includes the cross-shaped stem portions 193a and 193b and the plurality of third fine branch portions 193c extending from the cross-shaped stem portions 193a and 193b in the diagonal direction. An entire shape of the third basic electrode 193 is quadrangular.

The cross-shaped stem portions 193a and 193b include a horizontal stem portion 193b and a vertical stem portion 193a perpendicular to the horizontal stem portion 193b.

The third basic electrode 193 including the cross-shaped stem portions 193a and 193b is divided into four regions Da, Db, Dc, and Dd based on the horizontal stem portion 193b and the vertical stem portion 193a. Each of the four regions includes the plurality of third fine branch portions 193c.

The third fine branch portions 193c positioned in a first region Da obliquely extend from the horizontal stem portion 193b or the vertical stem portion 193a in a left upward direction, and the third fine branch portions 193c positioned in a second region Db obliquely extend from the horizontal stem portion 193b or the vertical stem portion 193a in a left downward direction. The third fine branch portions 193c positioned in a third region Dc obliquely extend from the horizontal stem portion 193b or the vertical stem portion 193a in a right upward direction, and the third fine branch portions 193c positioned in a fourth region Dd obliquely extend from the horizontal stem portion 193b or the vertical stem portion 193a in a right downward direction.

The four regions Da, Db, Dc, and Dd divided based on the horizontal stem portion 193b or the vertical stem portion 193a correspond to four regions D1, D2, D3, and D4 divided based on each side of the integrated plate electrode 192a, respectively. That is, extension directions of the fine branch portions in each region are the same as each other, and alignment direction of the liquid crystal molecules aligned by the fine branch portions are also the same as each other.

Fine slits in which the electrodes are removed are positioned between the third fine branch portions 193c neighboring to each other.

The third fine branch portions 193c form an angle of approximately 45 degrees or 135 degrees with respect to the gate line 121 or the horizontal stem portion 193b. In addition, the third fine branch portions 193c of two neighboring regions Da, Db, Dc, and Dd may be perpendicular to each other. However, according to an embodiment, an angle formed by the third fine branch portions 193c and the gate line 121 or the horizontal stem portion 193b may be appropriately adjusted in consideration of display characteristics such as visibility of the liquid crystal display, or the like.

Some of the third fine branch portions 193c extend to form a wide region, thereby receiving a voltage from the second drain electrode 175b exposed through the second contact hole 185b.

Here, sides of the third fine branch portions 192c distort an electric field to generate a horizontal component of the electric field determining an inclination direction of the liquid crystal molecules 31. The horizontal component of the electric field is substantially horizontal to the sides of the third fine branch portions 193c. Therefore, the liquid crystal molecules 31 are inclined in a direction that is in parallel with a length direction of the third fine branch portions 193c. Since the third basic electrode 193 of the second sub-pixel electrode 191b includes the four regions Da to Dd in which length directions of the third fine branch portions 193c are different from each other, directions in which the liquid crystal molecules 31 are inclined are approximately four directions, and four domains in which alignment directions of the liquid crystal molecules 31 are different from each other are formed in a liquid crystal layer 3. When directions in which the liquid crystal molecules are inclined are various as described above, a reference viewing angle of the liquid crystal display becomes large.

In addition, the second sub-pixel electrode 191b includes the second basic electrode 194.

The second basic electrode 194 include one horizontal stem portion 194b extending in the column direction, the vertical stem portion 194a positioned at one end of the horizontal stem portion 194b so as to be perpendicular to the horizontal stem portion 194b, and the plurality of second fine branch portions 194c extending from both sides of the horizontal stem portion 194b in the diagonal direction

The horizontal stem portion 194b is connected to the vertical stem portion 194a positioned at the left of the horizontal stem portion 194b and perpendicular to one end of the horizontal stem portion 194b.

The second fine branch portions 194c extending from the horizontal stem portion 194b obliquely extend in a direction in which they become distant from the vertical stem portion 194a.

Therefore, according to an embodiment shown in FIG. 5, in the case in which the vertical stem portion 194a is connected to the horizontal stem portion 194b so that the vertical stem portion 194a is positioned at the left of one pixel area, the second fine branch portions 194c extend toward the right. On the other hand, in the case in which the vertical stem portion 194a is connected to the horizontal stem portion 194b so that the vertical stem portion 194a is positioned at the right of one pixel area, the second fine branch portions 194c extend toward the left.

The second basic electrode 194 includes a plurality of regions R1 and R2 divided based on the horizontal stem portion 194b, the vertical stem portion 194a, and a gap. That is, the horizontal stem portion 194b, the vertical stem portion 194a, and the gap form a boundary between the regions R1 and R2 neighboring to each other.

The plurality of second fine branch portions 194c positioned in the respective regions region R1 and R2 may obliquely extend outwardly from the horizontal stem portion 194b or the vertical stem portion 194a. The second fine branch portions 194c of different regions R1 and R2 included in the second basic electrode 194 may extend in different directions. Particularly, the second fine branch portions 194c of adjacent regions R1 and R2 may form an angle of about 90 degrees. Directions in which the second fine branch portions 194c extend in the respective regions R1 and R2 may be constant.

In detail, the second fine branch portions 194c of an upper region R1 in the region R1 and R2 divided based on the horizontal stem portion 194b and the vertical stem portion 194a may obliquely extend from the horizontal stem portion 194b in a right upward direction, and the second fine branch portions 194c in a lower region R2 may obliquely extend from the horizontal stem portion 194b in a right downward direction.

Correspondingly, the liquid crystal molecules 31 are aligned in a left downward direction in the upper region R1 and are aligned in a left upward direction in the lower region R2. That is, alignments of the liquid crystal molecule 31 may be divided into two different regions based on the horizontal stem portion 194b.

An acute angle formed by the second fine branch portions 194c and the horizontal stem portion 194b may be about 40 degree to about 45 degree, but is not limited thereto. That is, an acute angle formed by the second fine branch portions 194c and the horizontal stem portion 194b may be appropriately adjusted in consideration of display characteristics such as visibility of the liquid crystal display, or the like.

Here, the third basic electrode 193 and the second basic electrode 194 of the second sub-pixel electrode 191b may be connected to each other. The vertical stem portion 193a or the third fine branch portions 193c of the third basic electrode 193 and the second fine branch portion 194c of the second basic electrode 194 may be connected to each other.

As described above, as compared with a display device according to Comparative Example in which the first sub-pixel electrode 191a and the second sub-pixel electrode 191b include only the second basic electrode 194, in the display device according to an embodiment, the first sub-pixel electrode 191a includes the first basic electrode 192 having a high luminance and the second sub-pixel electrode 191b includes the third basic electrode 193 and the second basic electrode 194 forming alignments of the liquid crystal molecules 31 in various directions, thereby making it possible to improve visibility.

The first sub-pixel electrode 191a and the second sub-pixel electrode 191b are connected to the first drain electrode 175a or the second drain electrode 175b through the first contact hole 185a and the second contact hole 185b, respectively, and receive data voltages from the first drain electrode 175a and the second drain electrode 175b.

The shielding electrode 199 is positioned at an edge of one pixel so as to be overlapped with the data line 171. The shielding electrode 199 include vertical portions 196 extending along the data lines 171 and at least one horizontal portion 198 connecting neighboring vertical portions 196 to each other. The horizontal portion 198 of the shielding electrode may include an extended region formed at the center thereof.

The shielding electrode 199 receives the same voltage as a voltage applied to a common electrode (not shown). Therefore, an electric field is not generated between the shielding electrode 199 and the common electrode, and liquid crystal molecules between the shielding electrode 199 and the common electrode are not aligned. Therefore, liquid crystal between the shielding electrode 199 and the common electrode 270 become a black state. In the case in which the liquid crystal molecules show the black state, the liquid crystal molecules themselves may serve as a light blocking member. Therefore, in the display device according to an embodiment, a light blocking member positioned on a second insulation substrate and extending in the row direction may be omitted.

Next, an upper display panel 200 will be described.

The upper display panel 200 is made of transparent glass, plastic, or the like, and includes a light blocking member 220 positioned on a second insulation substrate 210 facing the first insulation substrate 110. The light blocking member 220 is also called a black matrix and prevents light leakage.

The light blocking member 220 according to an embodiment may extend in the column direction along the gate line 121.

In the case in which the color filter is positioned in a lower display panel 100, a color filter of the upper display panel 200 may be omitted. However, the present invention is not limited thereto. That is, the color filter may be positioned on the second insulation substrate 210. To the contrary, according to an embodiment, the light blocking member 220 positioned on the second insulation substrate 210 may be positioned on the first insulation substrate 110.

An overcoat 250 is positioned on the light blocking member 220. The overcoat 250 may be made of an (organic) insulating material, and prevents the light blocking member 220 from being exposed and provides a flat surface. The overcoat 250 may be omitted.

The common electrode 270 is positioned on the overcoat 250. The common electrode 270 may be made of the same material of a material of the pixel electrode 191, is formed in a plane shape, and receives a common voltage.

In addition, an alignment layer (not shown) may be positioned above the pixel electrode 191 and the common electrode 270.

The liquid crystal layer 3 is positioned between the lower display panel 100 and the upper display panel 200. The liquid crystal layer 3 has a negative dielectric anisotropy, and the liquid crystal molecules of the liquid crystal layer 3 are aligned so that long sides thereof are perpendicular to surfaces of the two display panels 100 and 200 in a state in which an electric field is not present.

The first sub-pixel electrode 191a and the second sub-pixel electrode 191b to which the data voltages are applied generate the electric field together with the common electrode 270 of the upper display panel 200 to determine an alignment direction of the liquid crystal molecules of the liquid crystal layer 3 positioned between two electrodes 191 and 270. A luminance of the light passing through the liquid crystal layer is controlled depending on the direction of the liquid crystal molecules determined as described above.

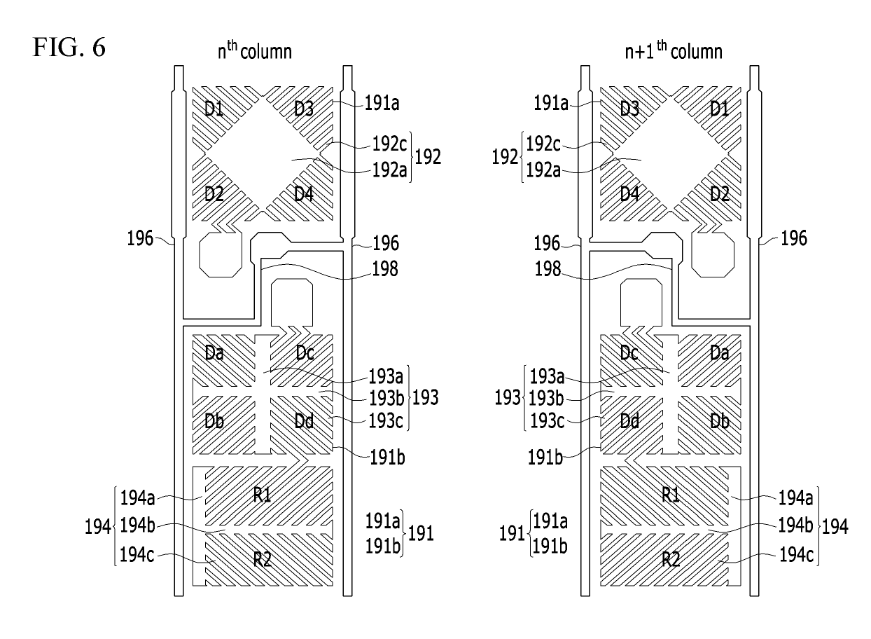

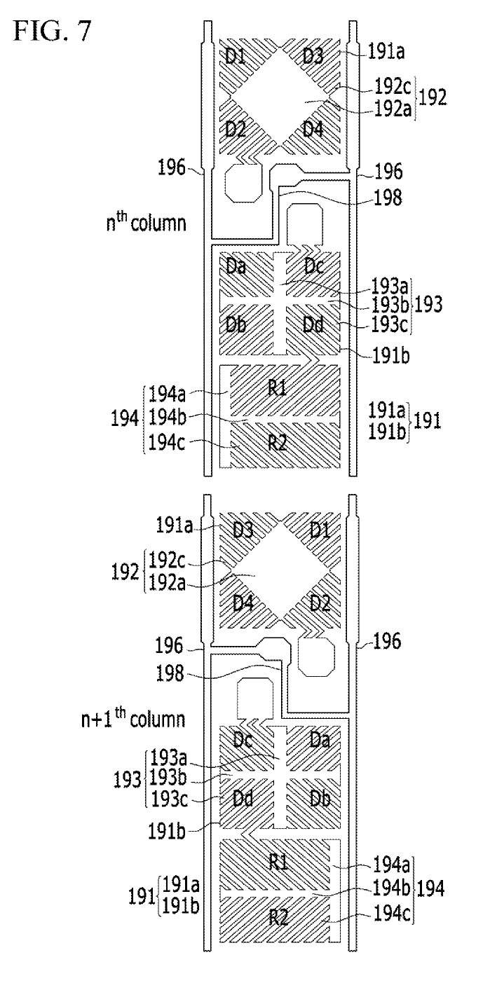

Hereinafter, an embodiment will be described with reference to FIGS. 6 and 7. FIGS. 6 and 7 are plan views showing a plurality of pixel electrode arranged according to an embodiment. Hereinafter, an arrangement of a plurality of pixel electrodes will be described, and a description for components that are the same as or similar to the above-mentioned components will be omitted.

First, as shown in FIG. 6, a plurality of vertical stem portions 194a adjacent to each other in the column direction may be positioned to be alternated with each other.

As an example, a vertical stem portion 194a positioned in an n^{th} column may be positioned at the left of one pixel area, and a vertical stem portion 194a positioned in an n+1^{th} column may be positioned at the right. That is, according to an embodiment, a pixel electrode positioned in the n^{th} column and a pixel electrode positioned in the n+1^{th} column may be symmetrical to each other based on a data line positioned between two pixel electrodes.

According to the arrangement of the pixel electrodes as described above, the pixel electrodes have various alignment directions of the liquid crystal molecules, thereby making it possible to improve visibility as compared with the case in which pixel electrodes having the same shape are disposed in a matrix form.

According to yet an embodiment, a plurality of vertical stem portions 194a adjacent to each other in the row direction may be positioned to be alternated with each other, as shown in FIG. 7.

As an example, a vertical stem portion 194a positioned in an n^{th} row may be positioned at the left of one pixel area, and a vertical stem portion 194a positioned in an n+1^{th} row may be positioned at the right.

According to an embodiment shown in FIG. 7, a pixel electrode positioned in the n^{th} row and a pixel electrode positioned in the n+1^{th} row may be symmetrical to each other based on a gate line positioned therebetween. According to the arrangement of the pixel electrodes as described above, the pixel electrodes have various alignment directions of the liquid crystal molecules, thereby making it possible to improve visibility as compared with the case in which pixel electrodes having the same shape are disposed in a matrix form.

Although only the case in which the pixel electrodes are arranged to be symmetrical to each other in the row direction or the column direction has been described in the present specification, the present invention is not limited thereto. That is, the above-mentioned embodiments may be variously combined with each other.

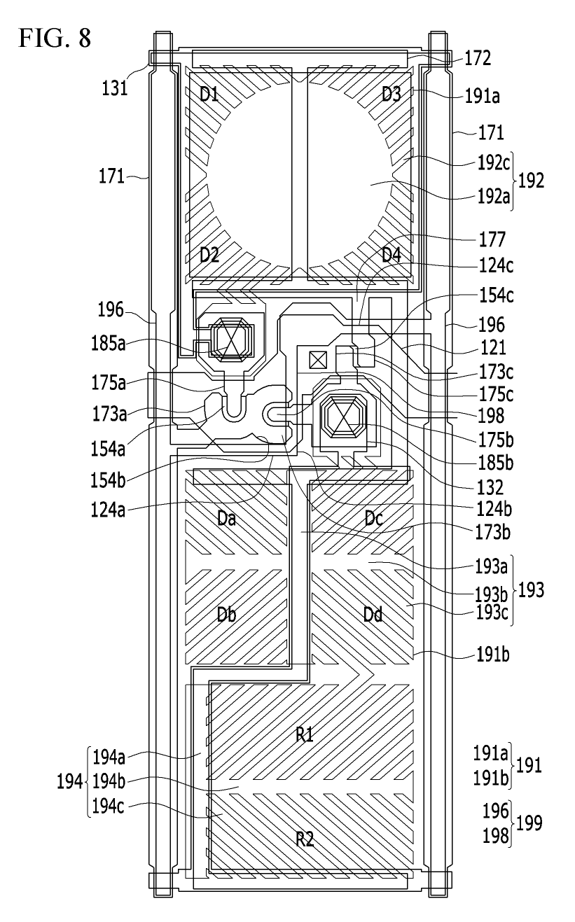

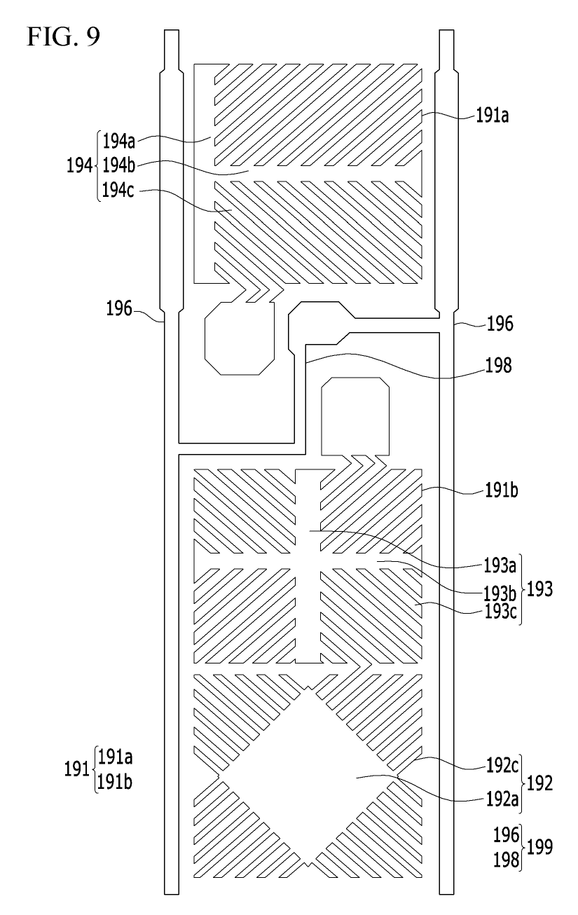

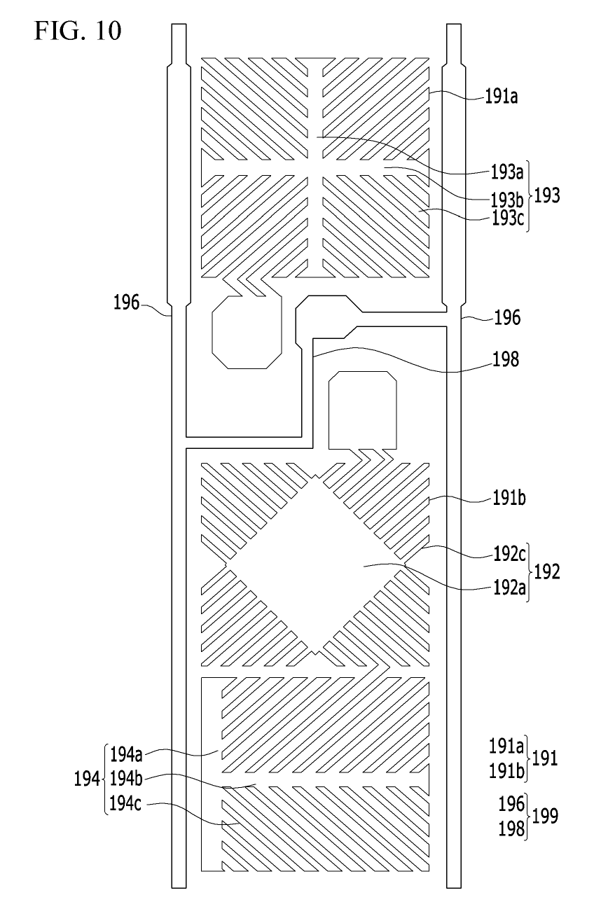

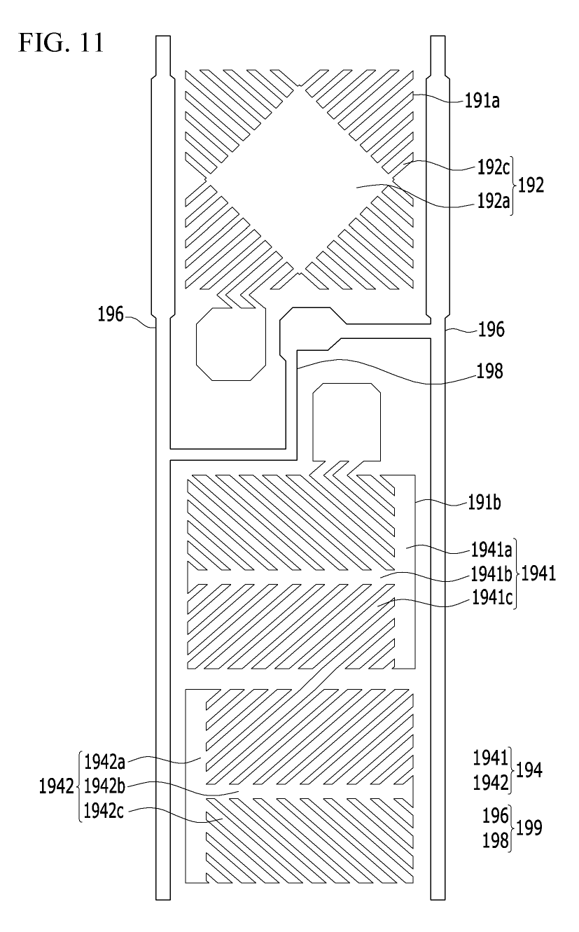

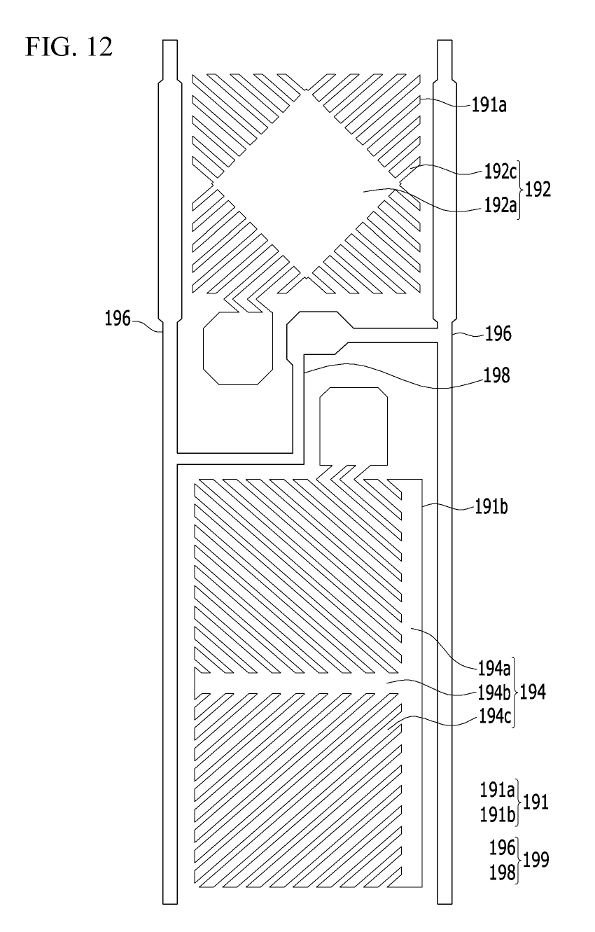

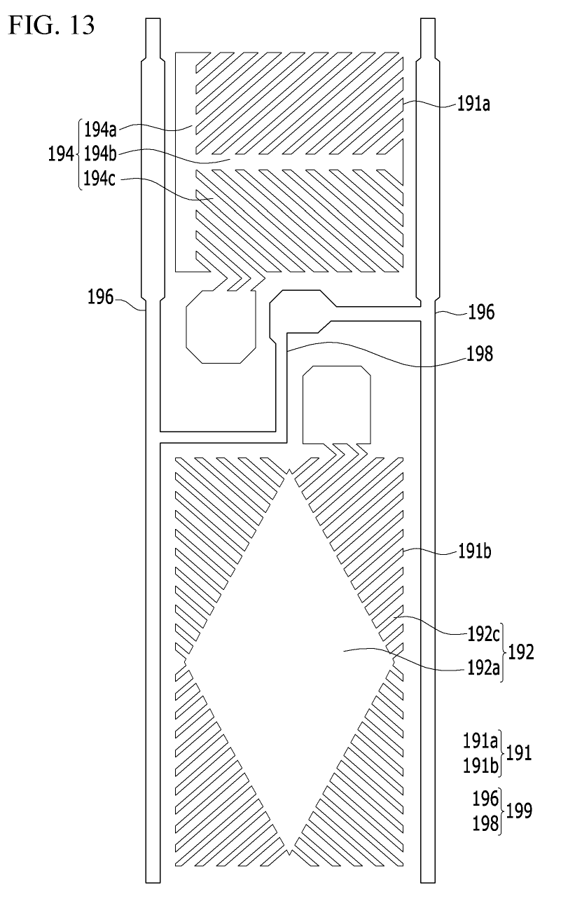

Hereinafter, various pixel electrodes 191 according to an embodiment will be described with reference to FIGS. 8 to 13.

FIGS. 8 to 13 are plan views of pixel electrode layers according to other embodiments. A display device according to the present embodiment is the same as the display device described above with reference to FIGS. 1 to 5 except that a shape, a layout, and a size of a pixel electrode are changed. Therefore, the same components will be denoted by the same reference numerals, and a repeated description for the same configurations will be omitted.

First, referring to FIG. 8, the pixel electrode 191 according to an embodiment includes a first sub-pixel electrode 191a and a second sub-pixel electrode 191b.

The first sub-pixel electrode 191a is a first basic electrode 192, and the second sub-pixel electrode 191b includes a third basic electrode 193 and a second basic electrode 194.

The first basic electrode 192 may include an integrated plate electrode 192a positioned at the center thereof and a plurality of first fine branch portions 192c extended from the integrated plate electrode 192a in the diagonal direction. An entire shape of the first basic electrode 192 is quadrangular.

Here, the integrated plate electrode 192a may be formed in a circular shape, and the first fine branch portions 192c are obliquely extended in a direction in which they become distant from the integrated plate electrode 192a.

The first basic electrode 192 includes four regions D1, D2, D3, and D4. Each of the four regions includes the plurality of first fine branch portions 192c.

The first fine branch portions 192c positioned in a first region D1 are obliquely extended from the integrated plate electrode 192a in a left upward direction, and the first fine branch portions 192c positioned in a second region D2 are obliquely extended from the integrated plate electrode 192a in a left downward direction. The first fine branch portions 192c positioned in a third region D3 are obliquely extended from the integrated plate electrode 192a in a right upward direction, and the first fine branch portions 192c positioned in a fourth region D4 are obliquely extended from the integrated plate electrode 192a in a right downward direction.

Fine slits in which the electrodes are removed are positioned between the first fine branch portions 192c neighboring to each other.

The first fine branch portions 192c form an angle of approximately 45 degrees or 135 degrees with respect to the gate line 121. In addition, the first fine branch portions 192c of two neighboring regions D1, D2, D3, and D4 may be perpendicular to each other. However, according to an embodiment, an angle formed by the first fine branch portions 192c and the gate line 121 may be appropriately adjusted in consideration of display characteristics such as visibility of the liquid crystal display, or the like.

Referring to FIGS. 9 and 10, the pixel electrode 191 according to an embodiment includes a first sub-pixel electrode 191a and a second sub-pixel electrode 191b.

As seen in FIG. 9, the first sub-pixel electrode 191a includes a second basic electrode 194, and the second sub-pixel electrode 191b may include a third basic electrode 193 and a first basic electrode 192. Here, according to an embodiment, positions of the third basic electrode 193 and the first basic electrode 192 of the second sub-pixel electrode 191b may be exchanged with each other. That is, although the case in which the third basic electrode 193 of the second sub-pixel electrode 191b is positioned above the first basic electrode 192 has been shown in an embodiment of FIG. 9, the first basic electrode 192 may be positioned above the third basic electrode 193 in an embodiment.

As seen in FIG. 10, the first sub-pixel electrode 191a includes a third basic electrode 193, and the second sub-pixel electrode 191b may include a first basic electrode 192 and a second basic electrode 194. Here, according to an embodiment, positions of the first basic electrode 192 and the second basic electrode 194 of the second sub-pixel electrode 191b may be exchanged with each other. That is, although the case in which the first basic electrode 192 of the second sub-pixel electrode 191b is positioned above the second basic electrode 194 has been shown in an embodiment of FIG. 10, the second basic electrode 194 may be positioned above the first basic electrode 192 in an embodiment.

Referring to FIG. 11, the pixel electrode 191 according to an embodiment includes a first sub-pixel electrode 191a and a second sub-pixel electrode 191b. The first sub-pixel electrode 191a may include a first basic electrode 192, and the second sub-pixel electrode 191b may include a second basic electrode 194.

Here, the second basic electrode 194 of the second sub-pixel electrode 191b includes a first horizontal basic electrode 1941 and a second horizontal basic electrode 1942.

The first horizontal basic electrode 1941 includes a first horizontal stem portion 1941b, a first vertical stem portion 1941a positioned at one end of the first horizontal stem portion 1941b, and a plurality of fourth fine branch portions 1941c extended from the first horizontal stem portion 1941b in the diagonal direction.

The second horizontal basic electrode 1942 includes a second horizontal stem portion 1942b, a second vertical stem portion 1942a positioned at one end of the second horizontal stem portion 1942b, and a plurality of fifth fine branch portions 1942c extended from the second horizontal stem portion 1942b in the diagonal direction.

Here, the first vertical stem portion 1941a and the second vertical stem portion 1942a are positioned to be alternated with each other.

In addition, the first horizontal basic electrode 1941 and the second horizontal basic electrode 1942 are connected to each other through the plurality of fourth fine branch portions 1941c and the plurality of fifth fine branch portions 1942c.

Referring to FIGS. 12 and 13, another pixel electrode 191 according to an embodiment includes a first sub-pixel electrode 191a and a second sub-pixel electrode 191b.

As seen in FIG. 12, the first sub-pixel electrode 191a includes a first basic electrode 192, and the second sub-pixel electrode 191b may include a second basic electrode 194.

Here, a ratio of areas of the first basic electrode 192 and the second basic electrode 194 may be about 1:2.

As seen in FIG. 13, the first sub-pixel electrode 191a includes a second basic electrode 194, and the second sub-pixel electrode 191b may include a first basic electrode 192.

Here, a ratio of areas of the second basic electrode 194 and the first basic electrode 192 may be about 1:2.

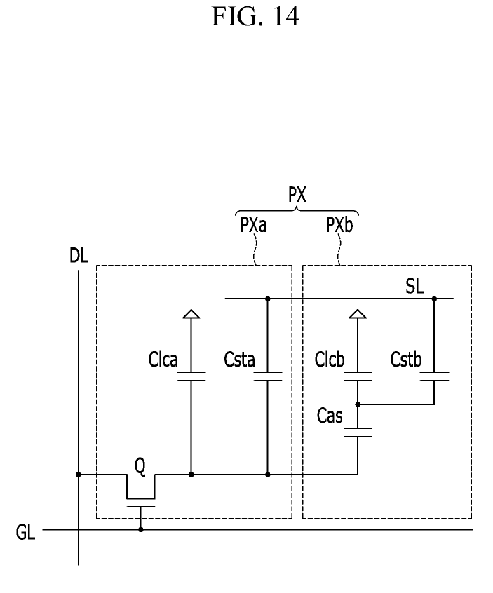

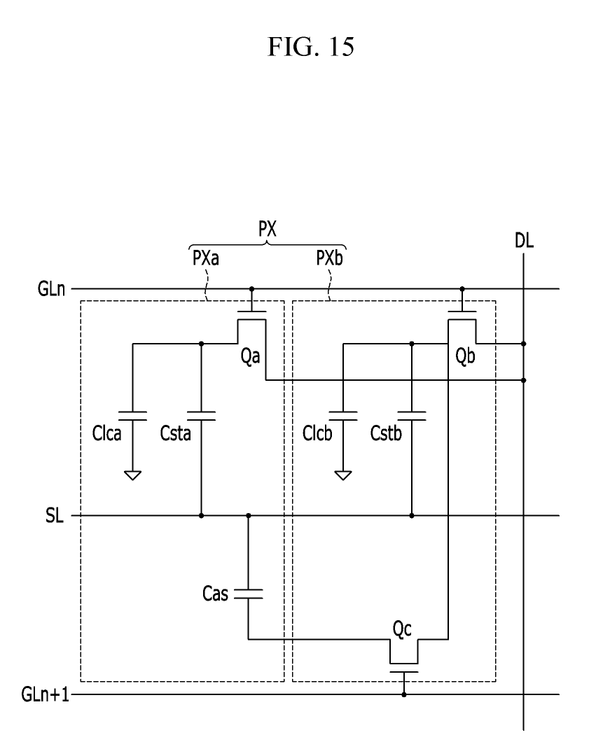

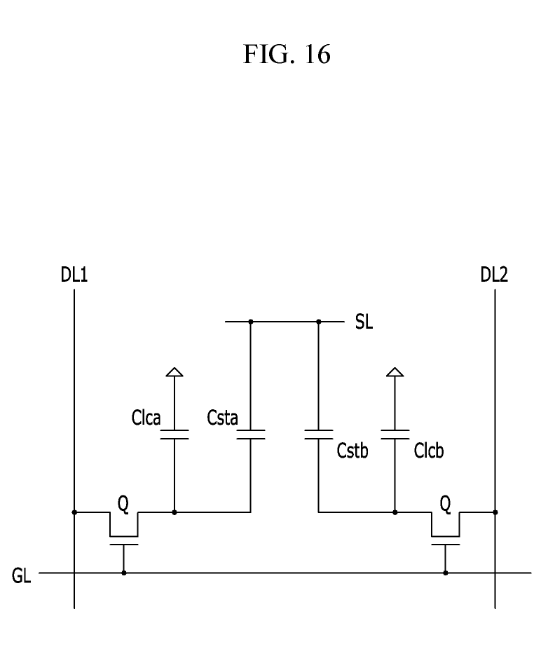

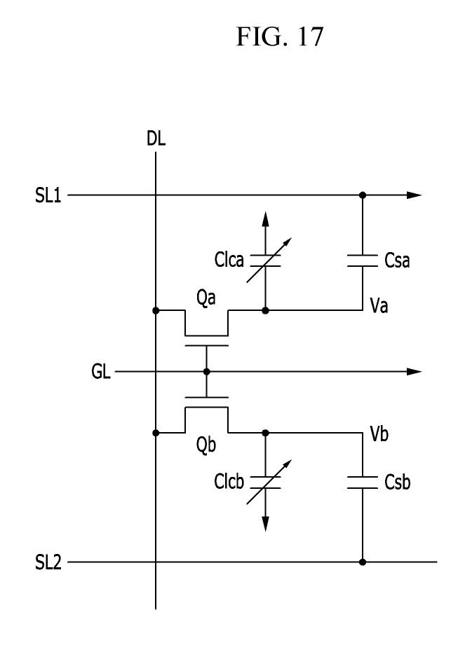

Hereinafter, a circuit diagram of a display device according to an embodiment will be described with reference to FIGS. 14 to 17. FIGS. 14 to 17 are circuit diagrams of one pixel according to an embodiment. Shapes of the gate line and the data line shown in FIGS. 2 to 4 may be changed as shown in FIGS. 14 to 17, which indicates a pixel arrange of FIGS. 14 to 17 having the shape of the pixel electrodes described above is possible.

Hereinafter, an embodiment of FIG. 14 will be described.

The liquid crystal display according to an embodiment includes signal lines including a plurality of gate lines GL, a plurality of data lines DL, and a plurality of sustain electrode lines SL and a plurality of pixels PX connected to the signal lines. Each pixel PX includes a pair of first and second sub-pixels PXa and PXb. A first sub-pixel electrode is formed in the first sub-pixel PXa, and a second sub-pixel electrode is formed in the second sub-pixel PXb.

The liquid crystal display according to an embodiment further includes a switching element Q connected to the gate line GL and the data line DL, a first liquid crystal capacitor Clca and a first sustain capacitor Csta connected to the switching element Q and formed in the first sub-pixel PXa, a second liquid crystal capacitor Clcb and a second sustain capacitor Cstb connected to the switching element Q and formed in the second sub-pixel PXb, and an auxiliary capacitor Cas formed between the switching element Q and the second liquid crystal capacitor Clcb.

The switching element Q, which is a three-terminal element such as a thin film transistor, or the like, provided in the lower display panel 100, has a control terminal connected to the gate line GL, an input terminal connected to the data line DL, and an output terminal connected to the first liquid crystal capacitor Clca, the first sustain capacitor Csta, and the auxiliary capacitor Cas.

One terminal of the auxiliary capacitor Cas is connected to the output terminal of the switching element Q, and the other terminal of the auxiliary capacitor Cas is connected to the second liquid crystal capacitor Clcb and the second sustain capacitor Cstb.

A voltage charged in the second liquid crystal capacitor Clcb becomes lower than a voltage charged in the first liquid crystal capacitor Clca by the auxiliary capacitor Cas, thereby making it possible to improve side visibility of the liquid crystal display.

Hereinafter, an embodiment of FIG. 15 will be described.

The liquid crystal display according to an embodiment includes signal lines including a plurality of gate lines GLn and GLn+1, a plurality of data lines DL, and a plurality of sustain electrode lines SL and a plurality of pixels PX connected to the signal lines. Each pixel PX includes a pair of first and second sub-pixels PXa and PXb. A first sub-pixel electrode is formed in the first sub-pixel PXa, and a second sub-pixel electrode is formed in the second sub-pixel PXb.

The liquid crystal display according to an embodiment further includes a first switching element Qa and a second switching element Qb connected to the gate line GLn and the data line DL, a first liquid crystal capacitor Clca and a first sustain capacitor Csta connected to the first switching element Qa and formed in the first sub-pixel PXa, a second liquid crystal capacitor Clcb and a second sustain capacitor Cstb connected to the second switching element Qb and formed in the second sub-pixel PXb, a third switching element Qc connected to the second switching element Qb and switched by the next stage of gate line GLn+1, and an auxiliary capacitor Cas connected to the third switching element Qc.

The first switching element Qa and the second switching element Qb, which are three-terminal elements such as thin film transistors, or the like, provided in the lower display panel 100, have control terminals connected to the gate line GLn, input terminals connected to the data line DL, and output terminals connected to the first liquid crystal capacitor Clca and the first sustain capacitor Csta, and the second liquid crystal capacitor Clcb and the second sustain capacitor Cstb, respectively.

The third switching element Qc, which is also a three-terminal element such as a thin film transistor provided in the lower display panel 100, has a control terminal connected to the next stage of gate line GLn+1, an input terminal connected to the second liquid crystal capacitor Clcb, and an output terminal connected to the auxiliary capacitor Cas.

One terminal of the auxiliary capacitor Cas is connected to the output terminal of the third switching element Qc, and the other terminal of the auxiliary capacitor Cas is connected to the sustain electrode line SL.

An operation of the liquid crystal display according to an embodiment will be described. When a gate-on voltage is applied to the gate line GLn, the first switching element and the second switching elements Qa and Qb connected to the gate line GLn are turned on, and a data voltage of the data line 171 is applied to the first and second sub-pixel electrodes.

Then, when a gate-off voltage is applied to the gate line GLn and the gate-on voltage is applied to the next stage of gate line(GLn+1), the first and second switching elements Qa and Qb are turned off, and the third switching element Qc is turned on. Therefore, electric charges of the second sub-pixel electrode connected to the output terminal of the second switching element Qb flow into the auxiliary capacitor Cas, such that a voltage of the second liquid crystal capacitor Clcb drops.

The side visibility of the liquid crystal display may be improved by making voltages charged in the first and second liquid crystal capacitors Clca and Clcb different from each other as described above.

Hereinafter, an embodiment of FIG. 16 will be described.

The liquid crystal display according to an embodiment includes signal lines including a plurality of gate lines GL, a plurality of data lines DL1 and DL2, and a plurality of sustain electrode lines SL and a plurality of pixels PX connected to the signal lines. Each pixel PX includes a pair of first and second liquid crystal capacitors Clca and Clab and first and second sustain capacitors Csta and Cstb.

Each sub-pixel includes one liquid crystal capacitor and one storage capacitor, and additionally includes one thin film transistor Q. Thin film transistors Q of two sub-pixels belonging to one pixel are connected to the same gate line GL, but are connected to different data lines DL1 and DL2. Different levels of data voltages are simultaneously applied to the different data lines DL1 and DL2 to allow the first and second liquid crystal capacitors Clca and Clcb of the two sub-pixels to be charged with different voltages. As a result, the side visibility of the liquid crystal display may be improved.

Hereinafter, an embodiment of FIG. 17 will be described.

The liquid crystal display according to an embodiment includes a gate line GL, a data line DL, a first power supply SL1, a second power supply line SL2, and a first switching element Qa and second switching element Qb connected to the gate line GL and the data line DL, as shown in FIG. 17.

The liquid crystal display according to an embodiment further includes an auxiliary step-up capacitor Csa and a first liquid crystal capacitor Clca connected to the first switching element Qa, and an auxiliary step-down capacitor Csb and a second liquid crystal capacitor Clcb connected to the second switching element Qb.

The first switching element Qa and the second switching element Qb are formed of a three-terminal element such as a thin film transistor, or the like. The first switching element Qa and the second switching element Qb are connected to the same gate line GL and the same data line DL, such that they are turned on at the same timing to output the same data signals.

Voltages having a form in which they are swung at a predetermined period are applied to the first power supply line SL1 and the second power supply line SL2. A first low voltage is applied to the first power supply line SL1 for a predetermined period (for example, 1H), and a first high voltage is applied to the first power supply line SL1 for the next predetermined period. A second high voltage is applied to the second power supply line SL2 for a predetermined period, and a second low voltage is applied to the second power supply line SL2 for the next predetermined period. Here, first and second periods are repeated plural times for one frame, such that the voltages having the form in which they are swung are applied to the first power supply line SL1 and the second power supply line SL2. Here, the first low voltage and the second low voltage may be the same as each other, and the first high voltage and the second high voltage may also be the same as each other.

The auxiliary step-up capacitor Csa is connected to the first switching element Qa and the first power supply line SL1, and the auxiliary step-down capacitor Csb is connected to the second switching element Qb and the second power supply line SL2.

A voltage Va of a terminal (hereinafter, referred to as a ‘first terminal’) of a portion at which the auxiliary step-up capacitor Csa is connected to the first switching element Qa becomes low when the first low voltage is applied to the first power supply line SL1 and becomes high when the first high voltage is applied to the first power supply line SL1. Then, as the voltage of the first power supply line SL1 is swung, the voltage Va of the first terminal is swung.

A voltage Vb of a terminal (hereinafter, referred to as a ‘second terminal’) of a portion at which the auxiliary step-down capacitor Csb is connected to the second switching element Qb becomes high when the second high voltage is applied to the second power supply line SL2 and becomes low when the second low voltage is applied to the second power supply line SL2. Then, as the voltage of the second power supply line SL2 is swung, the voltage Vb of the second terminal is swung.

As described above, even though the same data voltage is applied to the two sub-pixels, the voltages Va and Vb of the pixel electrodes of the two sub-pixels are changed depending on magnitudes of the voltages swung in the first and second power supply lines SL1 and SL2, thereby making it possible to make transmittances of the two sub-pixels different and improve the side visibility.

Embodiments described with reference to FIGS. 14 to 17 may include a line that extends parallel to the data line and vertically traverse the center of the display area of the pixel, thereby improving display quality.

In summary, referring to FIG. 1, FIG. 2, FIG. 3, FIG. 4, FIG. 5, FIG. 6, FIG. 7, FIG. 8, FIG. 9, FIG. 10, FIG. 11, FIG. 12, FIG. 13, FIG. 14, FIG. 15, FIG. 16, and FIG. 17, a display device may include a transistor Qa, a transistor Qb, a transistor Qc, a data line 171, a pixel electrode member 192, and a reference voltage line 172. The transistor Qa may include a source 173a and a source 175a. The transistor Qb may include a source 173b and a source 175b. The transistor Qc may include a source 175c and may be electrically connected to the transistor Qa or the transistor Qb. The data line 171 may be electrically connected to each of the source 173a and the source 173b. The pixel electrode member 192 may be electrically connected to the source 175a. The reference voltage line 172 may be electrically connected to the source 175c and may include a first bar (e.g., the top horizontal bar) and a second bar (e.g., the top vertical bar). The pixel electrode member 192 may overlap both the first bar and the second bar. The first bar may extend perpendicular to the data line 171. The second bar may extend parallel to the data line 171 and may be directly connected to a center portion of the first bar.

Two equal-length sections of the first bar may be positioned at two opposite sides with respect to the second bar.

The transistor Qc may include a source 173c, which may be electrically connected to the source 175a.

The display device may include a first shielding electrode (e.g., the left-side 196-198 combination illustrated in FIG. 6), a second shielding electrode (e.g., the right-side 196-198 combination illustrated in FIG. 6), and an insulating material layer (e.g., the color filter 230 illustrated in FIG. 3). The first shielding electrode may overlap the data line 171. The pixel electrode member 192 may be electrically insulated from the first shielding electrode and may be positioned between two portions of the first shielding electrode. The second shielding electrode may immediately neighbor the first shield electrode, may be asymmetrical, and may be a mirror image of the first shield electrode in a plan view of the display device. The insulating material layer may directly contact each of the first shielding electrode and the pixel electrode member 192.

The pixel electrode member 192 may include a base 192a and a branch 192c (e.g., a top-center branch 192c illustrated in FIG. 2 or FIG. 8). The branch 192c may overlap the first bar and may be directly connected to an edge of the base 192a. Two parallel sides of the branch 192c may be slanted with respect to the first bar. The second bar may divide the base 192a into two equal-size portions in a plan view of the display device.

The branch 192c may overlap both the first bar and the second bar. The branch 192c may be not longer than any other branch that is directly connected to the base 192a.

Referring to FIG. 2, the edge of the base 192a may be slanted with respect to the second bar.

Referring to FIG. 8, the edge of the base 192a may be curved. Each of the two equal-size portions of the base 192a may have an outer edge that is slanted with respect to the second bar or is curved.

The reference voltage line 172 may include a third bar (e.g., the horizontal bar directly connected to the portion 177 illustrated in FIG. 2 and FIG. 4), which may overlap the pixel electrode member 192. A first end of the second bar may be directly connected to the center portion of the first bar. A second end of the second bar may be directly connected to a center part of the third bar.

The display device may include a pixel electrode member 193, which may be electrically insulated from the pixel electrode member 192 and may be electrically connected to the source 175b. The reference voltage line 172 may include a third bar (e.g., the upper horizontal bar with reference to sub-pixel electrode 191b) and a fourth bar (e.g., the upper vertical bar with reference to sub-pixel electrode 191b). The pixel electrode member 193 may overlap both the third bar and the fourth bar. The third bar may extend perpendicular to the data line 171. The fourth bar may extend parallel to the data line 171 and may be directly connected to a center part of the third bar.

The transistor Qc may include a source 173c, which may be electrically connected to the source 175b.

The pixel electrode member 192 may include a base 192a and a branch 192c. The branch 192c may overlap the first bar and may be directly connected to an edge of the base 192a, wherein two parallel sides of the branch 192c may be slanted with respect to the first bar. The second bar divides the base 192a into two equal-size portions in a plan view of the display device. The pixel electrode member 193 may include a base 193a and a branch 193c. The branch 193c may overlap the third bar and may be directly connected to an edge of the base 193a, wherein two parallel sides of the branch 193c may be slanted with respect to the third bar. The fourth bar divides the base 193a into two equal-size parts in the plan view of the display device.

The edge of the base 192a may be slanted with respect to the fourth bar. The edge of the base 193a may be perpendicular to the fourth bar,

The edge of the base 192a may be curved. The edge of the base 193a may be perpendicular to the fourth bar,

The display device may include a pixel electrode member 194, which may be electrically connected to the pixel electrode member 193. The reference voltage line 172 may include a fifth bar (e.g., the middle horizontal bar with reference to sub-pixel electrode 191b) and a sixth bar (e.g., the lower vertical bar with reference to sub-pixel electrode 191b). The pixel electrode member 194 may overlap the sixth bar. The fifth bar may extend perpendicular to the data line 171 and may be shorter than at least one of the first bar and the third bar. A first end of the fifth bar may be directly connected to the fourth bar. A second end of the fifth bar may be directly connected to the sixth bar.

A length of the fifth bar may be less than or equal to a half of a length of the first bar.

The sixth bar may be as long as the second bar and may be not aligned with the second bar.

The sixth bar may be as long as the fourth bar and may be not aligned with the fourth bar.

According to embodiments, displayed image defects due to misalignment between upper and lower substrates may be minimized. According to embodiments, unwanted texture in a displayed image may be minimized or substantially prevented even if a size of a pixel area is minimized in a high resolution display device. While some embodiments have been described, possible embodiments are not limited to the described embodiments. Embodiments are intended to cover various modifications and equivalent arrangements applicable within the spirit and scope defined by the appended claims.

What is claimed is:

1. A display device comprising:
a first insulation substrate;
a thin film transistor positioned on the first insulation substrate;
a pixel electrode connected to the thin film transistor and including a first sub-pixel electrode and a second sub-pixel electrode;
a second insulation substrate facing the first insulation substrate; and
a common electrode positioned on the second insulation substrate,
wherein the pixel electrode includes a first basic electrode including an integrated plate electrode positioned at the center thereof and a plurality of fine branch portions extended from the integrated plate electrode in a diagonal direction, and a second basic electrode including a horizontal stem portion, a vertical stem portion positioned at one end of the horizontal stem portion, and a plurality of fine branch portions extended from the horizontal stem portion in the diagonal direction.

2. The display device of claim 1, wherein
the pixel electrode further includes a third basic electrode including cross-shaped stem portions and a plurality of fine branch portions extended from the cross-shaped stem portions in the diagonal direction.

3. The display device of claim 2, wherein:
the cross-shaped stem portions include a horizontal stem portion and a vertical stem portion perpendicular to the horizontal stem portion.

4. The display device of claim 2, wherein:
the first sub-pixel electrode includes the first basic electrode, and the second sub-pixel electrode includes the second basic electrode and the third basic electrode.

5. The display device of claim 4, wherein:
the second basic electrode and the third basic electrode are connected to each other.

6. The display device of claim 2, wherein:
the first sub-pixel electrode includes the second basic electrode, and the second sub-pixel electrode includes the first basic electrode and the third basic electrode.

7. The display device of claim 6, wherein:
the first basic electrode and the third basic electrode are connected to each other.

8. The display device of claim 2, wherein:
the first sub-pixel electrode includes the third basic electrode, and the second sub-pixel electrode includes the first basic electrode and the second basic electrode.

9. The display device of claim 8, wherein:
the first basic electrode and the second basic electrode are connected to each other.

10. The display device of claim 1, wherein:
the integrated plate electrode has a rhombus shape or a circular shape.

11. The display device of claim 1, wherein:
a plurality of vertical stem portions adjacent to each other in a column direction are positioned to be alternated with each other.

12. The display device of claim 1, wherein:
a plurality of vertical stem portions adjacent to each other in a row direction are positioned to be alternated with each other.

13. The display device of claim 1, wherein:
the first sub-pixel electrode includes the first basic electrode, and the second sub-pixel electrode includes the second basic electrode.

14. The display device of claim 13, wherein:
the second sub-pixel electrode includes a first horizontal basic electrode including a first horizontal stem portion, a first vertical stem portion positioned at one end of the first horizontal stem portion, and a plurality of fourth fine branch portions extended from the first horizontal stem portion in the diagonal direction, and a second horizontal basic electrode including a second horizontal stem portion, a second vertical stem portion positioned at one end of the second horizontal stem portion, and a plurality of fifth fine branch portions extended from the second horizontal stem portion in the diagonal direction.

15. The display device of claim 14, wherein:
the first vertical stem portion and the second vertical stem portion are positioned to be alternated with each other.

16. The display device of claim 13, wherein:
a ratio of areas of the first sub-pixel electrode and the second sub-pixel electrode is about 1:2.

17. The display device of claim 1, wherein:
the first sub-pixel electrode includes the second basic electrode, and the second sub-pixel electrode includes the first basic electrode.

18. The display device of claim 17, wherein:
a ratio of areas of the first sub-pixel electrode and the second sub-pixel electrode is about 1:2.

19. The display device of claim 1, wherein:
the display device has a curved shape.
